(19) United States
(12) Patent Application Publication
(10) Pub. No.: US 2026/0156742 A1
(43) Pub. Date: Jun. 4, 2026

(54) PCB MAGNETIC ASSEMBLY

(71) Applicant: Delta Electronics, Inc., Taoyuan City (TW)

(72) Inventors: Xueliang Chang, Shanghai (CN); Xingxin Zheng, Shanghai (CN)

(21) Appl. No.: 19/399,408

(22) Filed: Nov. 24, 2025

(30) Foreign Application Priority Data
Dec. 3, 2024 (CN) 202411761021.5

(51) Int. Cl. H05K 1/02; H01F 27/24; H01F 27/28

(52) U.S. Cl. CPC H05K 1/0298; H01F 27/24; H01F 27/28; H05K 2201/08; H05K 2201/10734

(57) ABSTRACT

A PCB magnetic assembly is disclosed and includes a multi-layer circuit board bracket structure and a magnetic component. The multi-layer circuit board bracket structure includes a multi-layer circuit board having an upper surface with an upper connection position and a lower surface with a lower connection position. The multi-layer circuit board includes an upper recess, a lower recess and a support layer. The support layer is an N-layer circuit board located between the upper recess and the lower recess, N≥1, and includes a copper layer and M through holes, M≥2. The copper layer is arranged around the through holes to form a winding, and includes a first terminal electrically connected to the upper connection position, and a second terminal electrically connected to the lower connection position. The magnetic component is arranged in the multi-layer circuit board bracket structure and partially passes through the through holes.

### CROSS-REFERENCE TO RELATED APPLICATION

This application claims priority to China Patent Application No. 202411761021.5, filed on Dec. 3, 2024. The entire contents of the above-mentioned patent application are incorporated herein by reference for all purposes.

### FIELD OF THE INVENTION

The present disclosure relates to an assembly structure of electronic components, and more particularly to a PCB magnetic assembly, which utilizes PCB to make the inductor winding, and has the two output terminals of the winding led out in the form of PCB pads to improve the flatness of the overall module and improve the welding quality.

### BACKGROUND OF THE INVENTION

With the rapid development and widespread application of microprocessors and communication equipment, the current flowing through the computing chips has increased rapidly, exceeding 1000 amperes. This change has brought great challenges to the voltage regulator that powers the chip.

Generally, the voltage regulators needs to have characteristics such as low output voltage, high current, high load transient performance and high efficiency. As an indispensable part of the voltage regulator, the performance, size and cost of the inductor are crucial to the entire system.

In the conventional manufacturing of inductor, the winding and the magnetic core are produced separately, and then the winding runs through the magnetic core to form an independent inductor, and an output terminal is formed on the surface of the inductor. On the one hand, this solution is affected by the processing accuracy. It is easy to cause the winding impedance and the inductive coupling coefficient to deviate greatly from the designed values. It is not conducive to engineering application and promotion. On the other hand, the assembly accuracy will affect the subsequent welding process of the inductor, and the positions of the winding and the magnetic core need to be manually trimmed. It is not conducive to mass production of the inductor modules. Furthermore, the unevenness of the output terminals of the inductor module will also affect the subsequent welding quality of the inductor module, thereby affecting the use of the inductor module.

In view of this, there is a need of providing a PCB magnetic assembly, which utilizes PCB to make the inductor winding, and has the two output terminals of the winding led out in the form of PCB pads, so as to improve the flatness of the overall module, improve the welding quality, and obviate the drawbacks encountered by the prior arts.

### SUMMARY OF THE INVENTION

In accordance with an aspect of the present disclosure, a PCB magnetic assembly is provided and includes a multi-layer circuit board bracket structure and a magnetic component. The multi-layer circuit board bracket structure includes a multi-layer circuit board having an upper surface and a lower surface opposite to each other, wherein an upper connection position and a lower connection position are disposed on the upper surface and the lower surface, respectively. The multi-layer circuit board includes an upper recess, a lower recess and a support layer, wherein the upper recess is recessed from the upper surface to the lower surface, and the lower recess is recessed from the lower surface to the upper surface, and the support layer is located between the upper recess and the lower recess, wherein the support layer is an N-layer circuit board, N≥1, and the support layer includes a copper layer and M through holes, M≥2, and the copper layer is arranged around the through holes to form a winding, wherein the copper layer includes a first terminal electrically connected to the upper connection position on the upper surface of the multi-layer circuit board, and a second terminal electrically connected to the lower connection position on the lower surface of the multi-layer circuit board, wherein the upper surface and the lower surface of the multi-layer circuit board form an upper surface and a lower surface of the PCB magnetic assembly. The magnetic component is arranged in the multi-layer circuit board bracket structure, wherein a portion of the magnetic component passes through the through holes of the support layer.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a PCB magnetic assembly according to a first embodiment of the present disclosure;

FIG. 2 is an exploded structural view illustrating the PCB magnetic assembly according to the first embodiment of the present disclosure from a top perspective;

FIG. 3 is an exploded structural view illustrating the PCB magnetic assembly according to the first embodiment of the present disclosure from a bottom perspective;

FIG. 4 is a schematic cross-sectional view illustrating the PCB magnetic assembly according to the first embodiment of the present disclosure;

FIG. 5 is a structural perspective view illustrating an electronic module using a PCB magnetic assembly according to a second embodiment of the present disclosure;

FIG. 6 is an exploded structural view illustrating the electronic module using the PCB magnetic assembly according to the second embodiment of the present disclosure from a top perspective;

FIG. 7 is an exploded structural view illustrating the electronic module using the PCB magnetic assembly according to the second embodiment of the present disclosure from a bottom perspective;

FIG. 8 is a schematic cross-sectional view illustrating the electronic module using the PCB magnetic assembly according to the second embodiment of the present disclosure;

FIG. 9 to FIG. 14 are schematic diagrams showing a manufacturing process of a PCB magnetic assembly according to a third embodiment of the present disclosure;

FIG. 15 is a schematic cross-sectional view illustrating the PCB magnetic assembly according to the third embodiment of the present disclosure;

FIG. 16 is an exploded structural view illustrating a PCB magnetic assembly according to a fourth embodiment of the present disclosure;

FIG. 17 is a schematic cross-sectional view illustrating the PCB magnetic assembly according to the fourth embodiment of the present disclosure;

FIG. 18 is a structural perspective view illustrating a PCB magnetic assembly according to a fifth embodiment of the present disclosure;

FIG. 19 is an exploded structural view illustrating the PCB magnetic assembly according to the fifth embodiment of the present disclosure; and

FIG. 20 is a schematic cross-sectional view illustrating the PCB magnetic assembly according to the fifth embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

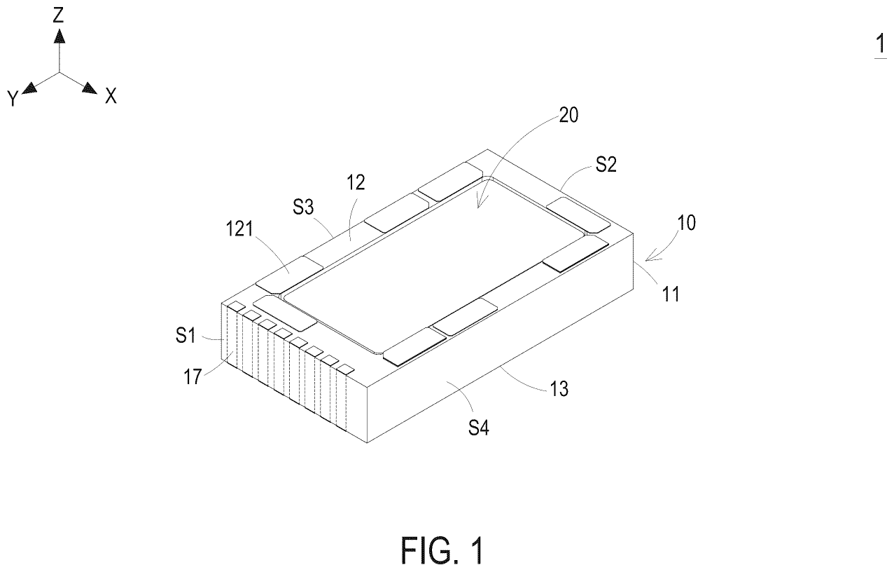

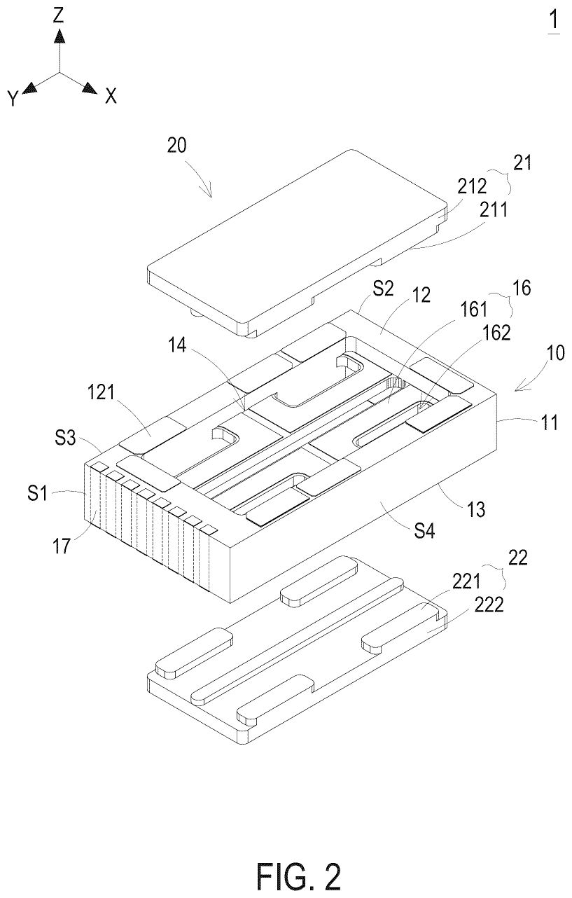

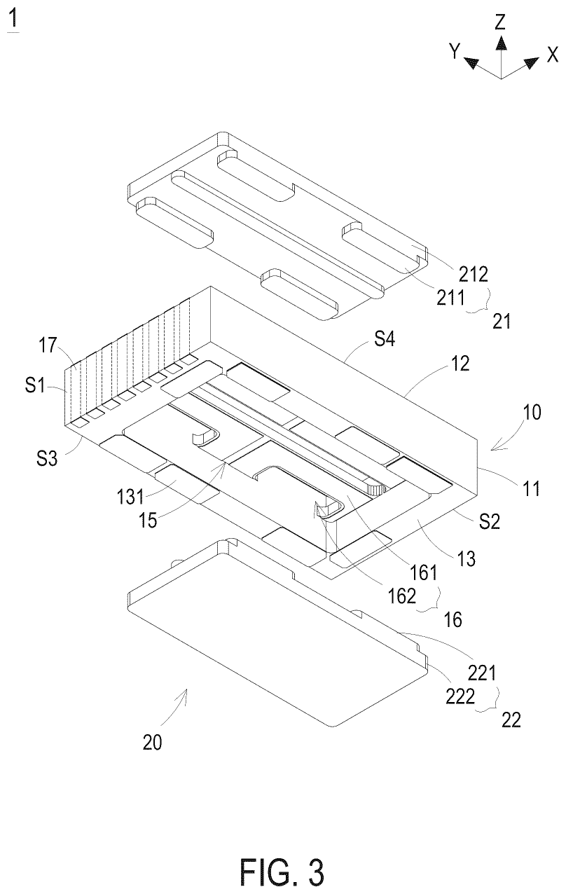

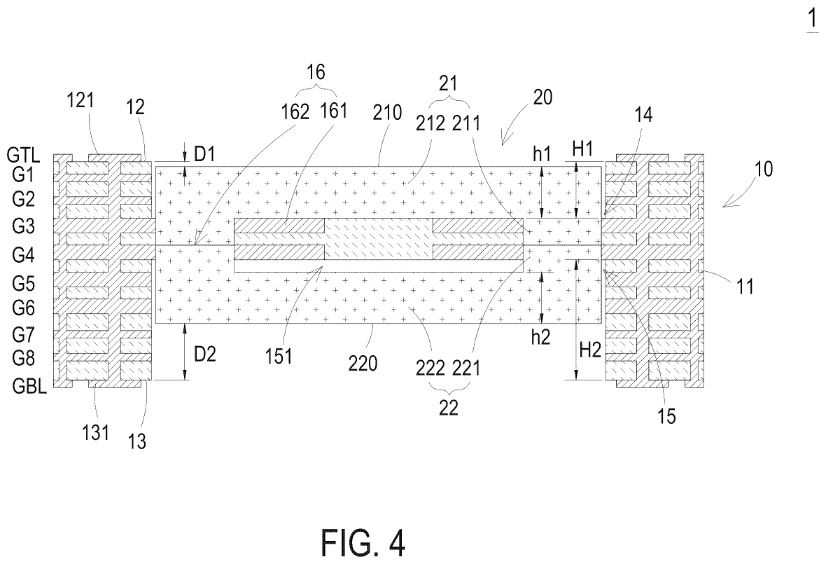

FIG. 1 is a structural perspective view illustrating a PCB magnetic assembly according to a first embodiment of the present disclosure. FIG. 2 is an exploded structural view illustrating the PCB magnetic assembly according to the first embodiment of the present disclosure from a top perspective. FIG. 3 is an exploded structural view illustrating the PCB magnetic assembly according to the first embodiment of the present disclosure from a bottom perspective. FIG. 4 is a schematic cross-sectional view illustrating the PCB magnetic assembly according to the first embodiment of the present disclosure. In the embodiment, the present disclosure provides a PCB magnetic assembly 1 including a multi-layer circuit board bracket structure 10 and a magnetic component 20. The multi-layer circuit board bracket structure 10 includes a multi-layer circuit board 11 having an upper surface 12 and a lower surface 13 opposite to each other. In the embodiment, an upper connection position 121 and a lower connection position 131 are disposed on the upper surface 12 and the lower surface 13, respectively. In the embodiment, the multi-layer circuit board 11 includes an upper recess 14, a lower recess 15 and a support layer 16. The upper recess 14 is recessed along a direction (i.e., the inverse Z axial direction) from the upper surface 12 to the lower surface 13, and the lower recess 15 is recessed along a direction (i.e., the Z axial direction) from the lower surface 13 to the upper surface 12. In the embodiment, the support layer 16 is located between the upper recess 14 and the lower recess 15. Preferably but not exclusively, the support layer 16 is an N-layer circuit board of a multi-layer board structure, N≥1. In the embodiment, the support layer 16 includes a copper layer 161 and M through holes 162, M≥2. Preferably but not exclusively, the copper layer 161 is arranged around the through holes 162 to form a winding. In addition, the copper layer 161 includes a first terminal electrically connected to the upper connection position 121 on the upper surface 12 of the multi-layer circuit board 11, and a second terminal electrically connected to the lower connection position 131 on the lower surface 13 of the multi-layer circuit board 11. Notably, in the embodiment, the upper surface 12 and the lower surface 13 of the multi-layer circuit board 11 form an upper surface 12 and a lower surface 13 of the PCB magnetic assembly 1. The magnetic component 20 is arranged in the multi-layer circuit board bracket structure 10. In an embodiment, the magnetic component 20 is a snap-fit magnetic core, and includes an upper magnetic core 21 and a lower magnetic core 22. The upper magnetic core 21 and the lower magnetic core 22 partially passes through the through holes 162 of the support layer 16 to be connected with each other, so that the magnetic component 20 is snap-fit into the multi-layer circuit board bracket structure 10.

Notably, the PCB magnetic assembly 1 sets the winding of the magnetic component 20 in the multi-layer circuit board bracket structure 10, and the two output terminals of the winding are allowed to be led out to the upper connection position 121 on the upper surface 12 and the lower connection position 131 on the lower surface 13 in the form of welding pads. The upper surface 12 and the lower surface 13 of the PCB magnetic assembly 1 are composed of the upper surface 12 and the lower surface 13 of the multi-layer circuit board 11. The overall flatness of the PCB magnetic assembly 1 is much higher than that of the traditional assembly solutions, and the welding quality of the upper connection position 121 and the lower connection position 131 can be improved greatly.

In the embodiment, the multi-layer circuit board bracket structure 10 includes a first lateral side S1 and a second lateral side S2 opposite to each other, and a third lateral side S3 and a fourth lateral side S4 opposite to each other. The first lateral side S1, the second lateral side S2, the third lateral side S3 and the fourth lateral side S4 all maintain a spacing with the upper recess 14 and the lower recess 15. In other words, the upper recess 14 and the lower recess 15 are defined at designated areas of the inner edge of the multi-layer circuit board 11. In this way, the multi-layer circuit board 11 can be milled with at least one pair of upper recess 14 and the lower recess 15 in the designated area through a depth-controlled milling process. The upper recess 14 and the lower recess 15 are distributed on the upper surface 12 and lower surface 13 of the multi-layer circuit board 11, and the positions of the upper recess 14 and the lower recess 15 are opposite to each other. The support layer 16 is disposed between each pair of the upper recess 14 and the lower recess 15. The support layer 16 is composed of at least one layer of circuit board. According to the size and the shape of the upper magnetic core 21 and the lower magnetic core 22, at least two through holes 162 are drilled between the upper recess 14 and the lower recess 15 to facilitate the subsequent assembly of the upper magnetic core 21 and the lower magnetic core 22. In the embodiment, the upper magnetic core 21 and the lower magnetic core 22 are assembled, for example, by bonding through the through hole 162 between the upper recess 14 and the lower recess 15. The upper magnetic core 21 and the lower magnetic core 22 only need to be placed in the upper recess 14 and the lower recess 15 respectively to bond the upper magnetic column 211 and the lower magnetic column 221. Since the multi-layer circuit board bracket structure 10 produced by the PCB process has high dimensional accuracy, there is no need to manually trim the positions of the upper magnetic core 21 and the lower magnetic core 22. That is beneficial to improving the production yield of the module and reducing the production cost. Certainly, the present disclosure is not limited thereto.

In the embodiment, the support layer 16 forms the winding in accordance with the copper layer 161 disposed in a specific area, and then the winding is electrically connected to the upper connection position 121 on the upper surface 12 of the multi-layer circuit board 11 and the lower connection position 131 on the lower surface 13 the connections of electroplating punching or electroplating punching combined with inner layer routing. As shown in FIG. 4, in the embodiment, the multi-layer circuit board 11 can determine the controlled depth milling areas where the upper recess 14 and the lower recess 15 need to be formed in accordance to the shape and the size of the upper magnetic core 21 and the lower magnetic core 22. Then, the depth-controlled milling process is performed downward from the GTL layer until the G3 layer to be exposed, and the depth-controlled milling process is performed upward from the GBL layer until the G4 layer to be exposed. The G3 layer and the G4 layer are the support layer 16 of this embodiment. Thereafter, the through holes 162 are punched to between the upper recess 14 and the lower recess 15 according to the shapes and the sizes of the upper magnetic column 211 and the lower magnetic column 221 and run through the G3 layer and the G4 layer for installing the upper magnetic column 211 and the lower magnetic column 221. Preferably but not exclusively, in the embodiment, the copper cladding of the G3 layer and the G4 layer are configured to form partial windings according to the copper layer 161 in a specific area. Moreover, an upper connection position 121 and a lower connection position 131 are formed on the upper surface 12 (i.e., the GTL layer) and the lower surface 13 (i.e., the GBL layer) of the multi-layer circuit board 11, respectively. The windings of the G3 layer and the G4 layer are electrically connected to the upper connection position 121 and the lower connection position 131 by the connections of electroplating punching or electroplating punching combined with inner layer routing. That is, the multi-layer circuit board 11 includes an internal wiring for signal transmission through. In addition, the support layer 16 with the multi-layered structure is served as a transformer with a primary side and a secondary side disposed therein to provide transformer function applications. In the embodiment, the first lateral side surface S1, the second lateral side surface S2, the third lateral side surface S3 and the fourth lateral side surface S4 further include a board-edge copper plating layer 17 for signal transmission. Certainly, the present disclosure is not limited thereto. The PCB magnetic assembly 1 produced by using the multi-layer circuit board bracket structure 10 in combination with the magnetic component 20 has the characteristic of high flatness accuracy. Thereby, the technology of setting the winding into the PCB magnetic assembly 1 further improves the consistency of the impedance and the inductive coupling coefficients.

On the other hand, since the upper surface 12 and the lower surface 13 of the PCB magnetic assembly 1 are composed of the upper surface 12 and the lower surface 13 of the multi-layer circuit board 11, the magnetic component 20 is arranged in the multi-layer circuit board bracket structure 10 and the overall flatness is not affected while setting the magnetic component 20. Therefore, the upper magnetic core 21 of the magnetic component 20 does not exceed the upper surface 12 of the multi-layer circuit board 11, and a height difference D1 is maintained between the upper surface 210 of the upper magnetic core 21 and the upper surface 12 of the multi-layer circuit board 11. Similarly, the lower magnetic core 22 of the magnetic component 20 does not exceed the lower surface 13 of the multi-layer circuit board 11, and a height difference D2 is maintained between the lower surface 220 of the lower magnetic core 22 and the lower surface 13 of the multi-layer circuit board 11. In the embodiment, the multi-layer circuit board bracket structure 10 forms the upper recess 14 with a depth H1 on the upper surface 12 of the multi-layer circuit board 11 through the depth-controlled milling process, and forms the lower recess 15 with a depth H2 on the lower surface 13 of the multi-layer circuit board 11 through the depth-controlled milling process. In addition, the upper magnetic core 21 includes the upper magnetic column 211 and the upper magnetic cover 212, and the upper magnetic cover 212 has a height h1. The lower magnetic core 22 includes the lower magnetic column 221 and the lower magnetic cover 222. The lower magnetic cover 222 has a height h2. When the upper magnetic column 211 of the upper magnetic core 21 and the lower magnetic column 221 of the lower magnetic core 22 are bonded through the through hole 162 between the upper recess 14 and the lower recess 15, the upper magnetic cover 212 of the upper magnetic core 21 is more closely attached to the bottom surface of the upper recess 14. At this time, the height h1 of the upper magnetic cover 212 is the height of the upper surface 210 of the magnetic component 20 relative to the bottom of the upper recess 14, which does not exceed the depth H1 of the upper recess 14. Therefore, the upper surface 210 of the upper magnetic core 21 will not exceed the upper recess 14 after assembly. In addition, when the upper magnetic column 211 of the upper magnetic core 21 and the lower magnetic column 221 of the lower magnetic core 22 are bonded through the through hole 162 between the upper recess 14 and the lower recess 15, the lower magnetic cover 222 of the lower magnetic core 22 is not limited to fit the bottom surface of the lower recess 15. That is, a spacing space 151 is allowed to be retained. At this time, the height h2 of the lower magnetic cover 222 is smaller than the height of the lower surface 220 of the magnetic component 20 relative to the bottom surface of the lower recess 15 and smaller than the depth H2 of the lower recess 15. Therefore, the lower surface 220 of the lower magnetic core 22 will not exceed the lower recess 15 after assembly. Certainly, the form of the magnetic component 20 and the way of disposing the magnetic component in the multi-layer circuit board bracket structure 10 are adjustable according to the practical requirements, and the present disclosure is not limited thereto.

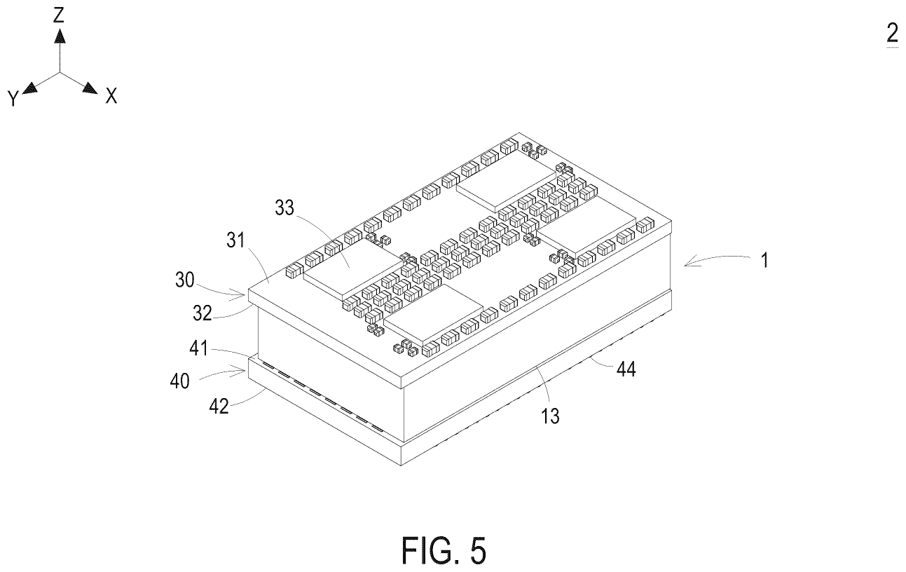

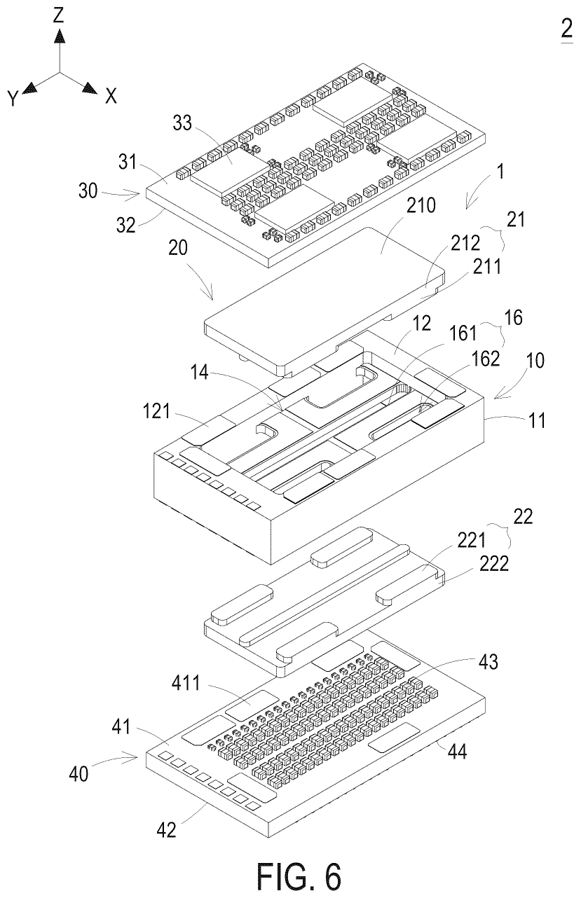

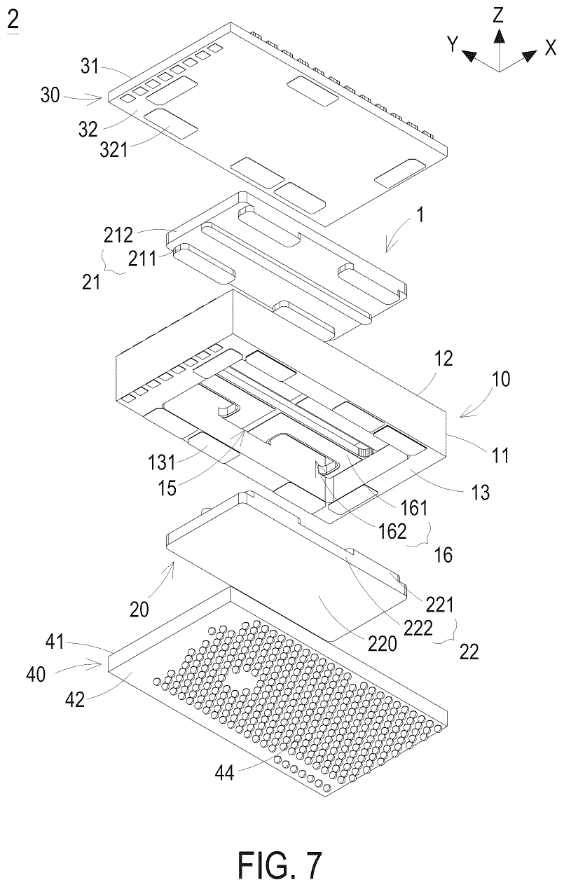

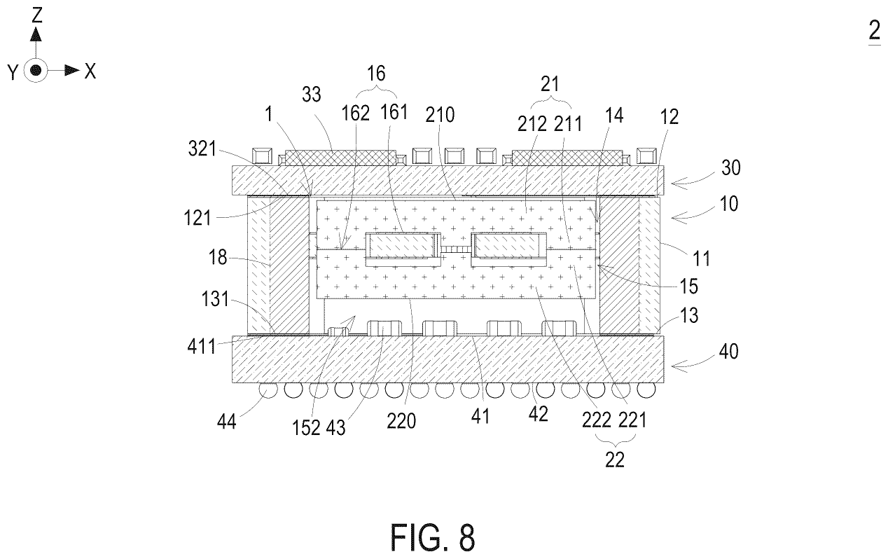

FIG. 5 is a structural perspective view illustrating an electronic module using a PCB magnetic assembly according to a second embodiment of the present disclosure. FIG. 6 is an exploded structural view illustrating the electronic module using the PCB magnetic assembly according to the second embodiment of the present disclosure from a top perspective. FIG. 7 is an exploded structural view illustrating the electronic module using the PCB magnetic assembly according to the second embodiment of the present disclosure from a bottom perspective. FIG. 8 is a schematic cross-sectional view illustrating the electronic module using the PCB magnetic assembly according to the second embodiment of the present disclosure. In the embodiment, the structures, elements and functions of the PCB magnetic assembly 1 are similar to those of the PCB magnetic assembly 1 of FIG. 1 to FIG. 4, and are not redundantly described herein. In the embodiment, the upper surface 12 and the lower surface 13 of the PCB magnetic assembly 1 are further connected to the first circuit board 30 and the second circuit board 40 respectively to form an electronic module 2. Preferably but not exclusively, the first circuit board 30 is a power board, and a power device 33 is disposed on the first circuit board upper surface 31. The upper connection position 121 on the upper surface 12 of the PCB magnetic assembly 1 is electrically connected to the power device 33 through the connection position 321 on the first circuit board lower surface 32. In addition, the lower connection position 131 on the lower surface 13 of the PCB magnetic assembly 1 is electrically connected to the connection position 411 on the second circuit board upper surface 41, and the second circuit board lower surface 42 of the second circuit board 40 has a plurality of electrical connection portions 44 for electrical transmission with an external device. Preferably but not exclusively, in the embodiment, the second circuit board 40 is a capacitor board, and the plurality of electrical connection portions 44 on the second circuit board lower surface 42 are BGA ball arrays. In other embodiments, the upper connection position 121 on the upper surface 12 and the lower connection position 131 on the lower surface 13 of the PCB magnetic assembly 1 are electrically connected to an external circuit or a component to form an electronic module 2, and the component is preferably a passive device, but not limited thereto. Notably, in the embodiment, the first circuit board 30 and the second circuit board 40 are further added on the PCB magnetic assembly 1 to connect the power circuit to form the electronic module 2 with power transmission function. In other embodiments, after the multi-layer circuit board bracket structure 10 and the magnetic component 20 are assembled to form the PCB magnetic assembly 1, the PCB magnetic assembly 1 is further electrically connected to other networks or external devices or components to form the electronic module 2 such as a power module. The PCB magnetic assembly 1 achieves the circuit connection and maintains the overall flatness through internal routing of the multi-layer circuit board 11 or PCB buried copper 18. If the overall module is added with the board-edge copper plating layer 17 (refer to FIG. 1), the function of the electronic module 2 and the freedom of electrical design can be greatly improved. For example, signals can be inputted from the external test module to facilitate module debugging. Certainly, the present disclosure is not limited thereto.

On the other hand, in the embodiment, when the multi-layer circuit board bracket structure 10 forms the upper recess 14 on the upper surface 12 and the lower recess 15 on the lower surface 13 of the multi-layer circuit board 11 through the depth-controlled milling process, a corresponding redundancy can be reserved. After the magnetic component 20 is snap-fit into the multi-layer circuit board bracket structure 10, an accommodation space 152 is formed between the bottom surface of the magnetic core of the magnetic component 20 (i.e., the lower surface 220 of the lower magnetic core 22) and the second circuit board upper surface 41 of the second circuit board 40 to accommodate components 43 on the second circuit board upper surface 41. It helps to reduce the height and the volume of the entire electronic module 2, and the overall power density is improved. Certainly, the present disclosure case is not limited thereto.

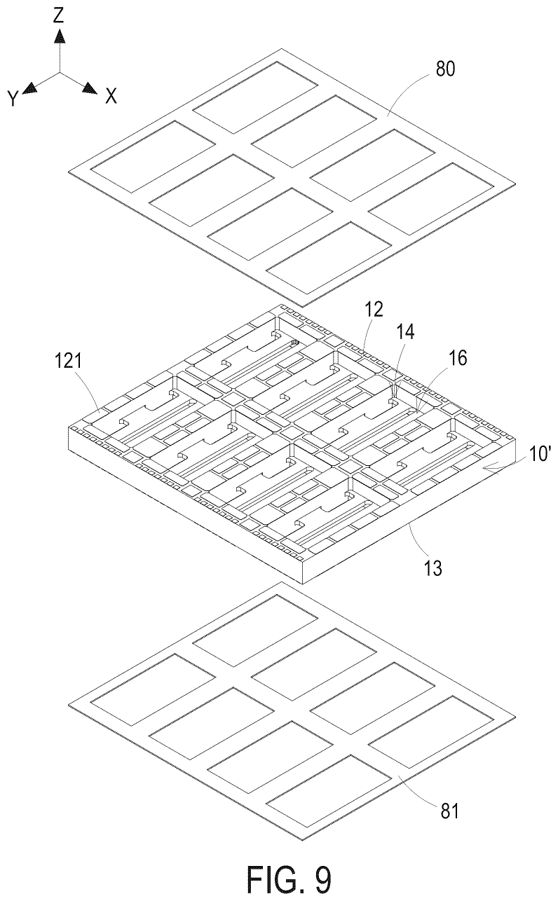

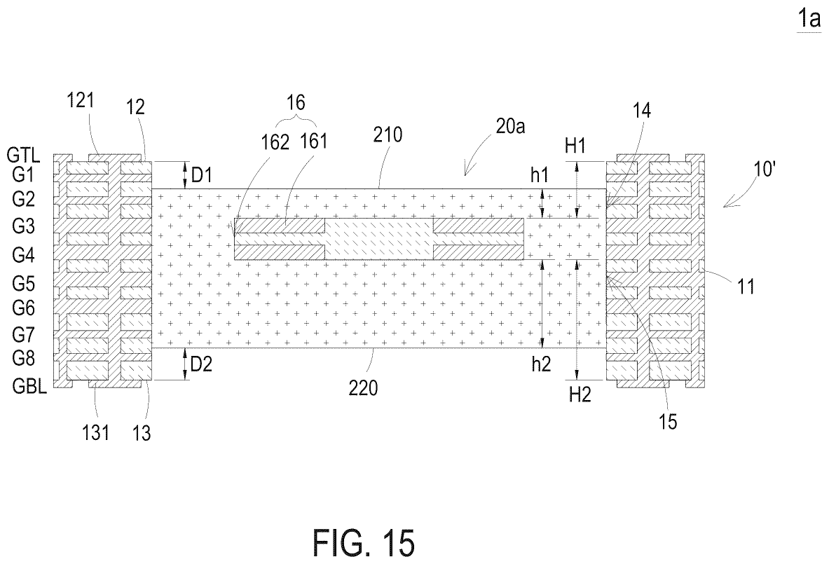

FIG. 9 to FIG. 14 are schematic diagrams showing a manufacturing process of a PCB magnetic assembly according to a third embodiment of the present disclosure. FIG. 15 is a schematic cross-sectional view illustrating the PCB magnetic assembly according to the third embodiment of the present disclosure. In the embodiment, the structures, elements and functions of the PCB magnetic assembly 1a are similar to those of the PCB magnetic assembly 1 of FIG. 1 to FIG. 4, and are not redundantly described herein. In the embodiment, the magnetic component 20a is a magnetic powder core and formed by pressing magnetic powder materials. The assembly of the multi-layer circuit board bracket structure 10′ and the magnetic component 20a can be completed by filling the upper recess 14, the lower recess 15 and the through hole 162 of the multi-layer circuit board 11 with magnetic powder. The following describes the assembly process of the multi-layer circuit board bracket structure 10′and the magnetic component 20a.

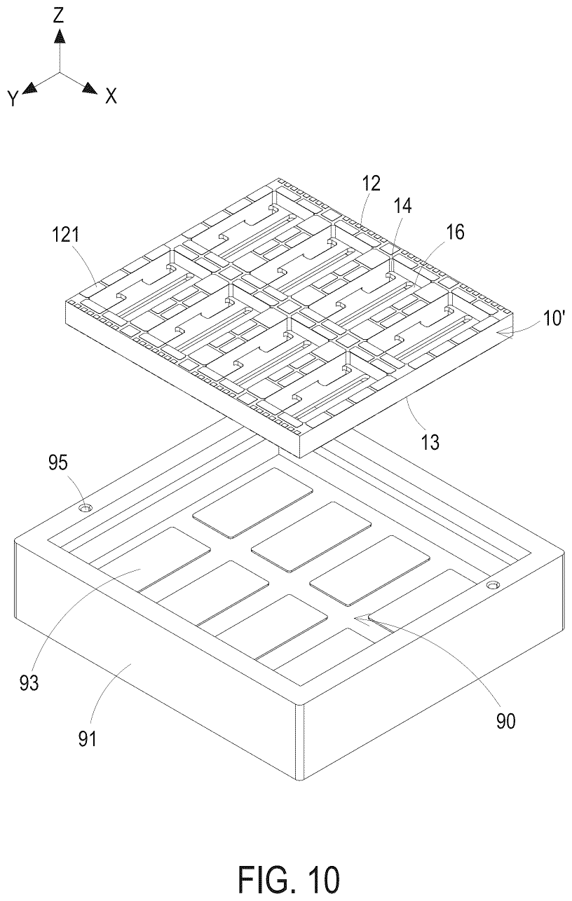

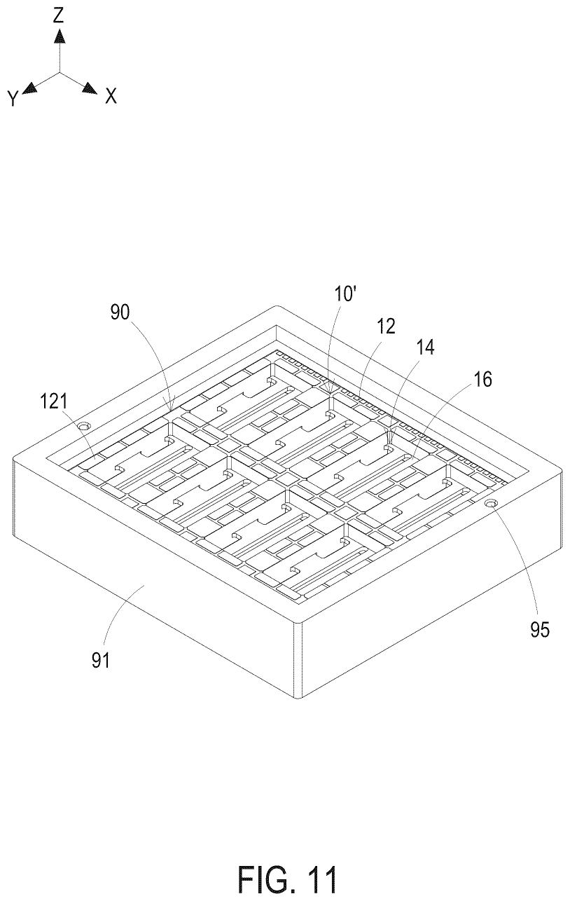

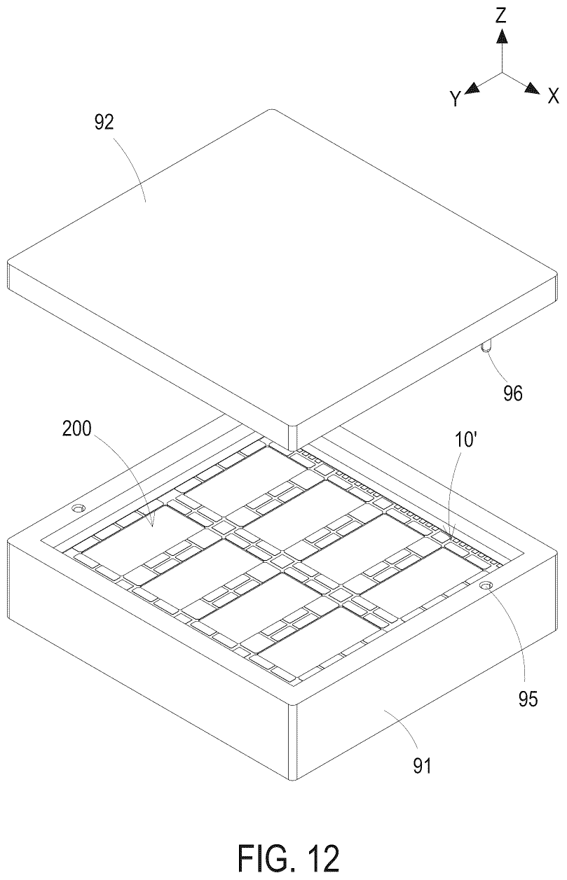

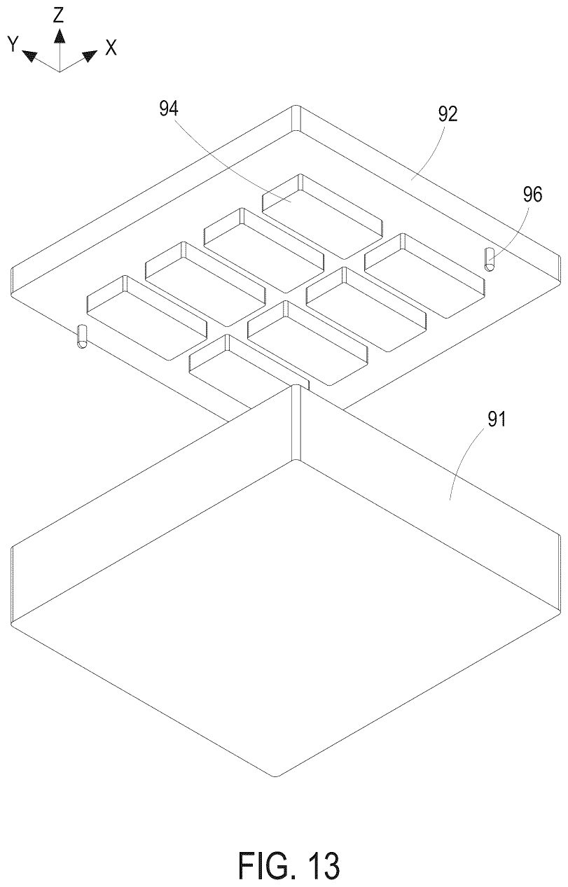

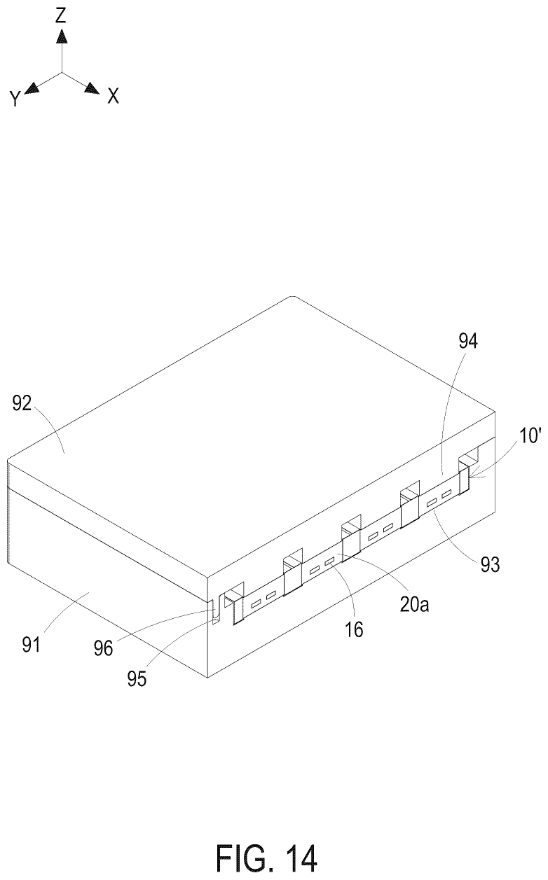

Firstly, as shown in FIG. 9, a protective film 80 is attached to the upper surface 12 of the multi-layer circuit board 11 to protect the upper connection position 121 on the upper surface 12 of the multi-layer circuit board 11. Similarly, a protective film 81 is attached to the lower surface 13 of the multi-layer circuit board 11 to protect the connection position 131 on the lower surface 13 of the multi-layer circuit board 11. Then, as shown in FIG. 10, the protected multi-layer circuit board bracket structure 10′ is placed into an internal space 90 of a lower mold 91, and the lower boss 93 in the internal space 90 is aligned to the lower recess 15. Next, as shown in FIG. 11, the magnetic powder 200 is injected through the upper recess 14 of the multi-layer circuit board 11. Preferably but not exclusively, the magnetic powder material 200 includes a magnetic wet material obtained by mixing magnetic powder and epoxy adhesive, and can fully fill the space between the lower recess 15 and the lower boss 93 through the upper recess 14 and the through hole 162. In one embodiment, the lower mold 91 is heated together with the multi-layer circuit board bracket structure 10′ and the magnetic powder 200. As the temperature gradually rises from room temperature to 180° C., the fluidity of the mixed powder is enhanced, presenting a slurry-like state. At the same time, the lower mold 91 is vibrated to allow the magnetic powder 200 to fill the upper recess 14, the through hole 162 and the lower recess 15 on the lower boss 93. Then, the upper mold 92 is installed in a matching manner with the alignment hole 95 of the lower mold 91 through the pin 96, so that the upper boss 94 can press the magnetic powder 200 in the upper recess 14, as shown in FIG. 12 and FIG. 13. The downward pressure is controlled and gradually increased until the mold is completely closed. In the embodiment, the downward pressure is gradually increased from 2 tons to 4 tons, and then the pressure is maintained for a period of time. The schematic diagram of the multi-layer circuit board bracket structure 10′ and the magnetic component 20a after assembly is shown in FIG. 14. After the pressure maintenance is completed, the multi-layer circuit board bracket structure 10′ with the magnetic powder embedded therein is formed integrally, removed from the mold and placed in an oven for drying and baking. In the embodiment, the drying and baking temperature is controlled at 150° C.˜200° C. for 3 hours˜5 hours to remove moisture in the magnetic powder and some organic matter in the epoxy glue, thereby avoiding the subsequent problem of the PCB magnetic assembly 1a being damp. The effect after molding is shown in FIG. 15.

In the embodiment, the upper surface 210 of the magnetic component 20a does not exceed the upper surface 12 of the multi-layer circuit board 11, and a height difference D1 is maintained between the upper surface 210 and the upper surface 12 of the multi-layer circuit board 11. Similarly, the lower surface 220 of the magnetic component 20 does not exceed the lower surface 13 of the multi-layer circuit board 11, and a height difference D2 is maintained between the lower surface 220 and the lower surface 13 of the multi-layer circuit board 11. In the embodiment, the multi-layer circuit board bracket structure 10 forms the upper recess 14 with a depth H1 on the upper surface 12 of the multi-layer circuit board 11 through the depth-controlled milling process, and forms a lower recess 15 with a depth H2 on the lower surface 13 of the multi-layer circuit board 11 through the depth-controlled milling process. In addition, the magnetic component 20 a has a height h1 relative to the support layer 16 at the bottom of the upper recess 14, which is smaller than the depth H1 of the upper recess 14. The magnetic component 20a has a height h2 relative to the support layer 16 at the bottom of the lower recess 15, which is smaller than the depth H2 of the lower recess 15. Notably, in the embodiment, the lower boss 93 of the lower mold 91 and the upper boss 94 of the upper mold 92 are designed to make the upper surface 210 and the lower surface 220 of the molded magnetic component 20a lower than the upper surface 12 of the multi-layer circuit board 11 by at least 0.2 mm, so as to avoid the subsequent SMT process from causing the surface of the magnetic powder core of the magnetic component 20a to be higher than the surface pad of the multi-layer circuit board 11 due to high-temperature warping of the circuit board. Thereby, the magnetic core upper surface 210 and the magnetic core lower surface 220 of the magnetic powder core are respectively recessed inward from the upper surface 12 and the lower surface 13 of the multi-layer circuit board 11, which can effectively reduce the problems of empty soldering and virtual soldering.

As shown in FIG. 15, the PCB magnetic assembly 1a is composed of a multi-layer circuit board bracket structure 10′ with the magnetic powder 200 embedded and integrally formed. The G1 layer, the G2 layer, the G3 layer, the G4 layer, the G5 layer, the G6 layer, the G7 layer, and the G8 layer are inner layers of the multi-layer circuit board 11 and used for internal routing and copper plating. The GTL layer and the GBL layer are surface layers of the multi-layer circuit board 11 and used for welding positions of the upper connection position 121 and the lower connection position 131. Preferably but not exclusively, electrical connections are achieved between the inner layers and between the inner layers and the surface layers of the multilayer circuit board 11 by electroplating and punching. By embedding the magnetic powder 200 into the integrally formed multi-layer circuit board bracket structure 10′, the manufacturing process of the PCB magnetic assembly 1a helps to eliminate the space waste caused by assembly tolerance. Moreover,, the gap between the magnetic component 20a and the multi-layer circuit board 11 is minimized, the effective volume of the magnetic core structure is increased, and the problem of magnetic core assembly tolerance is solved. At the same time, by adopting a process that combines the magnetic core molding with the multi-layer circuit board bracket structure 10′, the pressure resistance problem of the inductor winding is better solved.

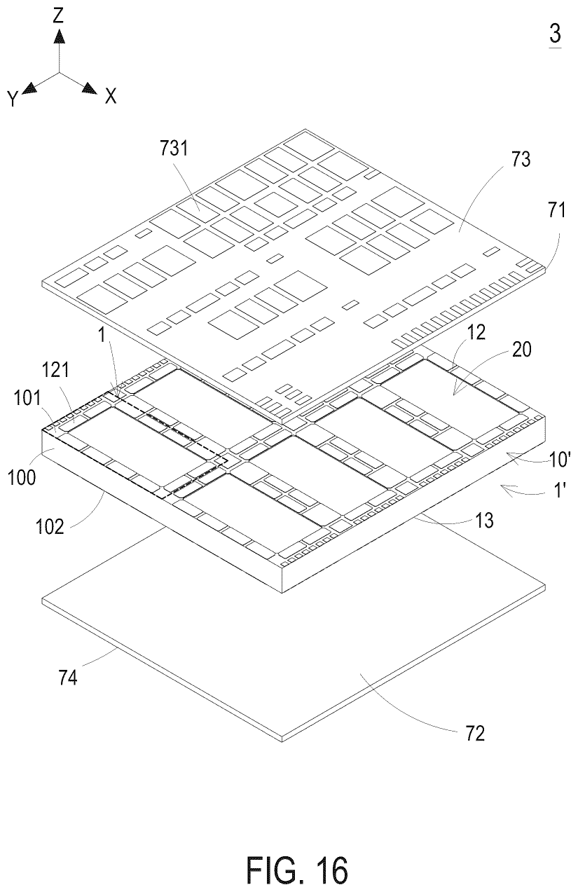

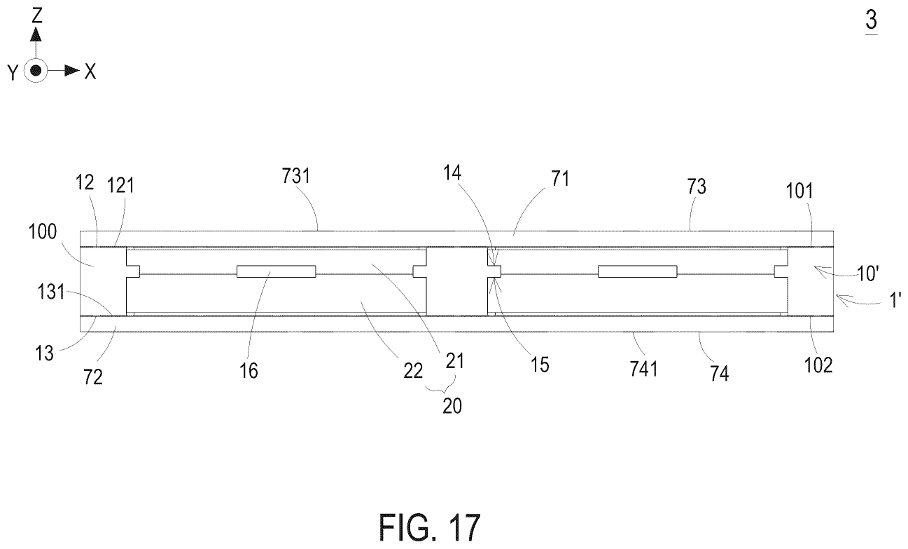

FIG. 16 is an exploded structural view illustrating a PCB magnetic assembly according to a fourth embodiment of the present disclosure. FIG. 17 is a schematic cross-sectional view illustrating the PCB magnetic assembly according to the fourth embodiment of the present disclosure. In the embodiment, the structures, elements and functions of the PCB magnetic assembly 1 are similar to those of the PCB magnetic assembly 1 of FIG. 1 to FIG. 4, and are not redundantly described herein. In the embodiment, a plurality of the aforementioned multiple PCB magnetic components 1 (refer to FIG. 1) are further connected through a continuous sheet 100 to form a PCB assembly set 1′. In the embodiment, the assembly set upper surface 101 and the assembly set lower surface 102 of the PCB assembly set 1′ are respectively connected to the circuit board 71 and the circuit board 72, and then form electrical transmission with an external network or device to form an electronic module set 3. Preferably but not exclusively, in other embodiments, the circuit board 71 and the circuit board 72 are replaced by, a plurality of circuit layers. In the embodiment, the upper surface 73 and the lower surface 74 of the electronic module set 3 include a plurality of electrical connection positions 731, 744 for placing a power device or connecting to the external network. In the embodiment, the electronic module set 3 is divided into pieces to form a plurality of electronic modules 2 (refer to FIG. 5) that works independently.

From the above, the PCB magnetic assembly 1 can also be manufactured through PCB manufacturing process, with the circuit layers being manufactured on the upper surface and the lower surface of the PCB magnetic assembly 1. It allows forming the PCB magnetic assembly 1 with a built-in magnetic component 20 that is not exposed. The pads on the upper surface and the lower surface of the PCB magnetic assembly 1 are connected to the components or electrical networks according to application requirements, and can be used as a complete power module. Furthermore, in addition to the production of single modules, the plurality of PCB magnetic assemblies 1 can also be produced in a continuous-sheet mode, with multiple PCB magnetic assemblies 1 forming a PCB assembly set 1′. Through PCB manufacturing process, the circuit layers are made or the circuit boards are added on the upper surface and the lower surface of the PCB assembly set 1′ to form a composite PCB module with electrical functions. Components are placed on both sides or a circuit network is formed through the internal wiring of the circuit board to transmit electricity to the exterior, so as to form a power module set 3. The power module set 3 can be further divided into multiple pieces to produce multiple power modules at one time. It is beneficial to improving the production efficiency of the modules and reducing the production cost. Certainly, the application of the PCB assembly set 1′ divided into the PCB magnetic components 1 or forming the power module set 3 can be adjusted according to the practical requirements, and the present disclosure is not limited thereto.

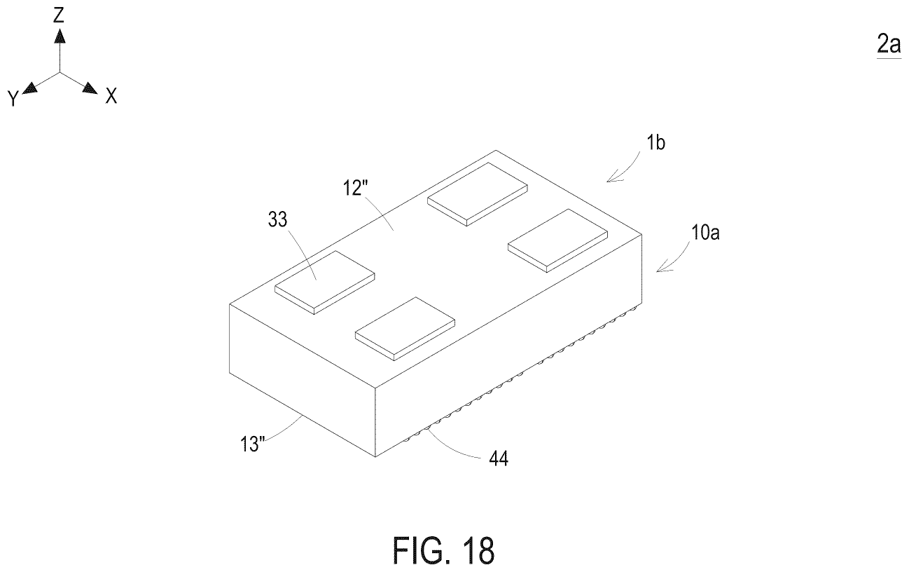

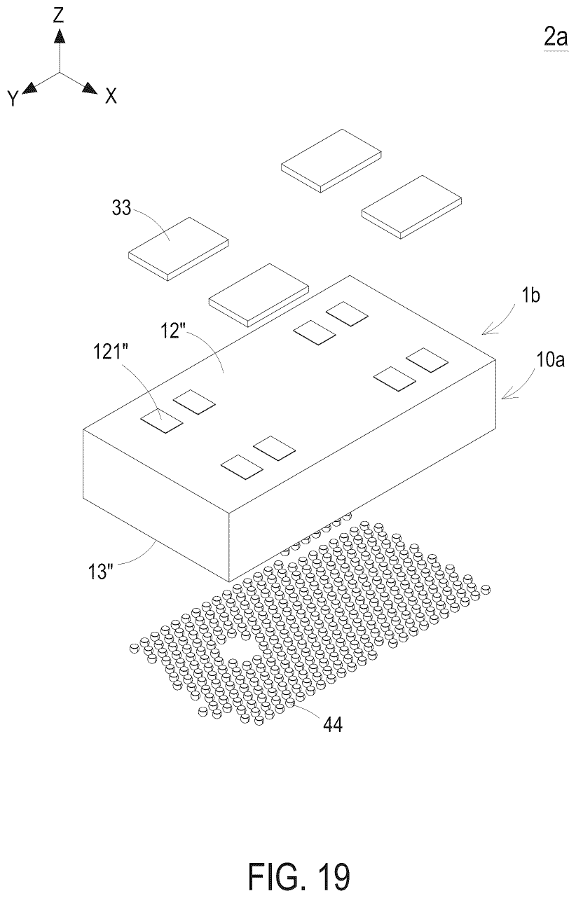

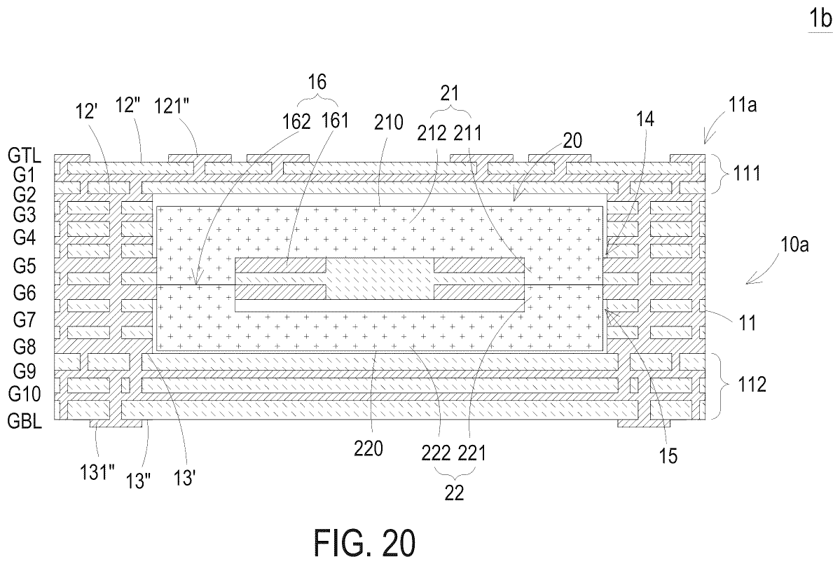

FIG. 18 is a structural perspective view illustrating a PCB magnetic assembly according to a fifth embodiment of the present disclosure. FIG. 19 is an exploded structural view illustrating the PCB magnetic assembly according to the fifth embodiment of the present disclosure. FIG. 20 is a schematic cross-sectional view illustrating the PCB magnetic assembly according to the fifth embodiment of the present disclosure. In the embodiment, the structures, elements and functions of the PCB magnetic assembly 1b are similar to those of the PCB magnetic assembly 1 of FIG. 1 to FIG. 4, and are not redundantly described herein. In the embodiment, the PCB magnetic assembly 1b is further processed by PCB manufacturing process, such as PP lamination, exposure, development, etching, and stripping. After the magnetic component 20 is snap-fit, an upper circuit layer 111 is formed on the upper surface 12′. The first outer surface 12″ of the upper circuit layer 111 has at least one upper connection position 121″ as a pad, allowing the power device 33 to be directly set. In the embodiment, at least one upper connection position 121″ is electrically connected to the output terminal of the winding in the PCB magnetic assembly 1b through inner layer routing and interlayer punching. In addition, after the magnetic component 20 is snap-fit, the PCB magnetic assembly 1b further includes a lower circuit layer 112 formed on the lower surface 13′ through PP pressing, exposure, development, etching, stripping and other PCB processes. Moreover, the second outer surface 13″ of the lower circuit layer 112 has a plurality of electrical connection portions 44. Preferably but not exclusively, the plurality of electrical connection portions 44 are BGA ball arrays. Thus, the multi-layer circuit board 11 assembled with the magnetic component 20 is further produced and formed into a multi-layer circuit board 11a with the complete first outer surface 12″ and the complete second outer surface 13″ through the PCB manufacturing processes, and the magnetic component 20 is embedded therein. In the embodiment, the G1 layer, G2 layer, G3 layer, G4 layer, G5 layer, G6 layer, G7 layer, G8 layer, G9 layer, and G10 layer are inner layers of the multi-layer circuit board 11a, which are used for internal routing and copper plating. The GTL layer and the GBL layer are surface layers of the multi-layer circuit board 11a and used for welding positions of the upper connection position 121″ and the lower connection position 131″. Electrical connections between the inner layers and between the inner layers and the surface layers of the multilayer circuit board 11a are achieved by electroplating and punching. In addition, the first outer surface 12″ and the second outer surface 13″ are served as two sides of the PCB magnetic assembly 1b, and connected with the components or the electrical networks to finally form an electronic module 2a. Since the PCB magnetic assembly 1b has complete two of the first outer surfaces 12″ and the second outer surfaces 13″, the area on which components can be placed on the PCB magnetic assembly 1b is greatly increased. After the PCB magnetic assembly 1b is assembled with the power device 33 and multiple electrical connection portions 44 through SMT and other process flows, the obtained electronic module 2a can be better applied to various products to achieve miniaturized and integrated application of inductor devices. Certainly, in other embodiments, the order, the number of layers and the method of combining the magnetic components 20 in the multi-layer circuit board bracket structure 10a in combination with the upper circuit layer 111 and/or the lower circuit layer 112 can be adjusted according to actual application requirements. The present disclosure is not limited thereto and not redundantly described hereafter.

In summary, the present disclosure provides a PCB magnetic assembly, which utilizes PCB to make the inductor winding, and has the two output terminals of the winding led out in the form of PCB pads, so as to improve the flatness of the overall module and improve the welding quality. By producing a multi-layer circuit board bracket structure and having an inductor winding disposed therein, the two output terminals of the winding are allowed to be led out in the form of pads. The overall flatness of the PCB magnetic assembly is much higher than that of traditional assembly solutions, and the welding quality is greatly improved. Furthermore, in the PCB production process, a controlled depth milling process is used to mill at least one pair of recesses in a designated area of the PCB. The two recesses are disposed on the upper surface and the lower surface of the multi-layer circuit board and located opposite to each other. A support layer is arranged between each pair of recesses, and composed of at least one layer of circuit board. According to the size and the shape of the magnetic core, at least two holes are drilled between the two recesses to facilitate the subsequent assembly of the magnetic core through the magnetic columns. The support layer can be copper-clad in specific areas to form the windings, and then connected to the upper surface and the lower surface of the multi-layer circuit board in electrical connection by electroplating punching or electroplating punching combined with PCB inner layer routing. The support layer in the multi-layer structure can be further configured as the primary side and the secondary side of the transformer to provide transformer function applications. The PCB magnetic assembly produced by combining the multi-layer circuit board bracket structure with the magnetic cores has the characteristics of high flatness accuracy. The technology of setting the winding into the PCB further improves the consistency of the impedance and the inductive coupling coefficients. In addition, the PCB magnetic assembly is allowed to transmit control signals and sampling signals through the connections of inner layer routing and punching of multi-layer circuit boards, so that the connections are used to connect the components or electrical networks disposed above or below the PCB magnetic assembly. Subsequently, a circuit layer or a circuit board connected to a power circuit is added on the PCB magnetic assembly, so as to form a module with power transmission and conversion functions. Since the PCB magnetic assembly has an internal wiring in the circuit board, it allows adding copper plating to the edge of the circuit board to improve the function of the entire module and the freedom of electrical design greatly. For example, signals can be inputted from the external test module to facilitate module debugging. On the other hand, the assembly of the magnetic cores can be bonded through the through hole between the two recesses, and the magnetic cores only need to be placed in the recesses to bond the magnetic columns. Since the multi-layer circuit board bracket structure produced by the PCB process has high dimensional accuracy, there is no need to manually trim the core position. That is beneficial to improving the production yield of the module and reducing the production costs. In addition, the assembly of the magnetic cores is not limited to the bonding of the upper magnetic core and lower magnetic core, but can also be composed of magnetic powder. That is, the magnetic core is formed by pressing the magnetic powder through a mold, so that the space waste caused by assembly tolerance is eliminated, the gap between the magnetic cores and the multi-layer circuit board bracket structure is minimized, the effective volume of the magnetic core structure is increased, and the problem of magnetic core assembly tolerance is solved. By adopting a process that combines the magnetic core molding with the multi-layer circuit board bracket structure, the pressure resistance problem of the inductor module is better solved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A PCB magnetic assembly, comprising:
a multi-layer circuit board bracket structure comprising a multi-layer circuit board having an upper surface and a lower surface opposite to each other, wherein an upper connection position and a lower connection position are disposed on the upper surface and the lower surface, respectively;
wherein the multi-layer circuit board includes an upper recess, a lower recess and a support layer, wherein the upper recess is recessed from the upper surface to the lower surface, and the lower recess is recessed from the lower surface to the upper surface, and the support layer is located between the upper recess and the lower recess, wherein the support layer is an N-layer circuit board, N≥1, and the support layer comprises a copper layer and M through holes, M≥2, and the copper layer is arranged around the through holes to form a winding, wherein the copper layer comprises a first terminal electrically connected to the upper connection position on the upper surface of the multi-layer circuit board, and a second terminal electrically connected to the lower connection position on the lower surface of the multi-layer circuit board, wherein the upper surface and the lower surface of the multi-layer circuit board form an upper surface and a lower surface of the PCB magnetic assembly; and
a magnetic component arranged in the multi-layer circuit board bracket structure, wherein a portion of the magnetic component passes through the through holes of the support layer.

2. The PCB magnetic assembly according to claim 1, wherein the multi-layer circuit board bracket structure comprises a first lateral side and a second lateral side opposite to each other, and a third lateral side and a fourth lateral side opposite to each other, wherein the first lateral side, the second lateral side, the third lateral side and the fourth lateral side all maintain a spacing with the upper recess and the lower recess, and the multi-layer circuit board comprises an internal wiring for signal transmission.

3. The PCB magnetic assembly according to claim 2, wherein the first lateral side, the lateral second side, the third lateral side and the fourth lateral side comprise a board-edge copper plating layer for signal transmission.

4. The PCB magnetic assembly according to claim 3, wherein the magnetic component is a snap-fit magnetic core, and comprises an upper magnetic core and a lower magnetic core.

5. The PCB magnetic assembly according to claim 4, wherein the magnetic component has a height difference with the upper surface and the lower surface of the multi-layer circuit board, respectively.

6. The PCB magnetic assembly according to claim 1, wherein the magnetic component is a magnetic powder core and formed by pressing magnetic powder materials.

7. The PCB magnetic assembly according to claim 6, wherein a magnetic core upper surface and a magnetic core lower surface of the magnetic powder core are respectively recessed inward from the upper surface and the lower surface of the multi-layer circuit board.

8. The PCB magnetic assembly according to claim 1, wherein the support layer is a multi-layer structure and includes a transformer with a primary side and a secondary side disposed therein.

9. The PCB magnetic assembly according to claim 6, wherein an upper surface of the magnetic component has a height not exceed a depth of the upper recess, and a lower surface of the magnetic component has a height not exceed a depth of the lower recess.

10. The PCB magnetic assembly according to claim 1, wherein the upper connection position on the upper surface and the lower connection position on the lower surface of the PCB magnetic component are electrically connected to an external circuit or a component to form an electronic module.

11. The PCB magnetic assembly according to claim 10, wherein the upper surface of the PCB magnetic component is connected to a first circuit board, and a power device is arranged on a first circuit board upper surface of the first circuit board.

12. The PCB magnetic assembly according to claim 10, wherein a second circuit board is connected to the lower surface of the PCB magnetic component, and a second circuit board lower surface of the second circuit board has a plurality of electrical connection portions for electrical transmission with an external device.

13. The PCB magnetic assembly according to claim 12, wherein an accommodating space is formed between a magnetic core bottom surface of the magnetic component and a second circuit board upper surface of the second circuit board for accommodating a component.

14. The PCB magnetic assembly according to claim 13, wherein the component is a passive device.

15. The PCB magnetic assembly according to claim 12, wherein the plurality of electrical connection portions on the second circuit board lower surface of the second circuit board are BGA ball arrays.

16. The PCB magnetic assembly according to claim 1, wherein an upper circuit layer is disposed on the upper surface of the PCB magnetic component, a first outer surface of the upper circuit layer has at least one connection position, and the at least one connection position is electrically connected to an output terminal of the winding of the PCB magnetic component.

17. The PCB magnetic assembly according to claim 1, wherein a lower circuit layer is disposed on the lower surface of the PCB magnetic component, and a second outer surface of the lower circuit layer has a plurality of electrical connection portions.

18. The PCB magnetic assembly according to claim 1, wherein a plurality of the PCB magnetic assemblies are connected through a continuous sheet to form a PCB assembly set.

19. The PCB magnetic assembly according to claim 18, wherein an assembly set upper surface and an assembly set lower surface of the PCB assembly set are respectively connected to a circuit board or multiple circuit layers to form electrical transmission with an external network or device, and form an electronic module set.

20. The PCB magnetic assembly according to claim 19, wherein the assembly set upper surface and the assembly set lower surface of the electronic module set include a plurality of electrical connection positions for placing a power device or connecting to the external network.

21. The PCB magnetic assembly according to claim 19, wherein the electronic module set is divided into multiple pieces to form a plurality of electronic modules that works independently.

22. The PCB magnetic assembly according to claim 1, wherein one end of the winding is led out from the upper connection position, and the other end of the winding is led out from the lower connection position.
